(19) United States
(12) Patent Application Publication
(10) Pub. No.: US 2026/0293632 A1
(43) Pub. Date: Sep. 24, 2026

(54) LOW MASS ION ETCH FOR CAVITY SHAPING ENGINEERING FOR CMOS DEVICES

(71) Applicant: Applied Materials, Inc., Santa Clara, CA (US)

(72) Inventors: John SPORRE, Fremont, CA (US); Sivanandha Krishnan KANAKASABAPATHY, Pleasanton, CA (US)

(21) Appl. No.: 19/084,576

(22) Filed: Mar. 19, 2025

(51) Int. Cl. H01L 21/768; H01L 21/02; H01L 21/3065; H01L 21/3205; H10D 62/00; H10D 62/832; H10D 62/834

(52) U.S. Cl. CPC H10W 20/056; H10D 62/021; H10D 62/832; H10D 62/834; H10P 14/20; H10P 14/3411; H10P 14/414; H10P 50/242; H10W 20/033

(57) ABSTRACT

A method of forming an electrical contact in a semiconductor structure includes performing a cavity shaping process to form a cavity in an exposed surface of an epitaxially grown region within a contact trench in a dielectric layer formed over a semiconductor region, the cavity shaping process including a reactive ion etching (RIE) process using a process gas consisting of an etch gas and a supporting inert gas including species less than 40 atomic mass (amu), and performing a selective epitaxial deposition process to form a contact epitaxial layer on an exposed surface of the cavity.

### BACKGROUND

### Field

Embodiments described herein generally relate to semiconductor device fabrication, and more particularly, to systems and methods of forming an electrical contact within a semiconductor structure.

### Description of the Related Art

Multi-gate metal-oxide-semiconductor field-effect transistors (MOSFETs), such as complementary metal-oxide semiconductor (CMOS) devices, pose challenges in manufacturability due to their three-dimensional (3D) designs and small sizes. In advanced CMOS devices, a cavity is formed in a source/drain region at a bottom of a contact trench and further a highly doped contact epitaxial layer is added in the cavity to increase a contact length and reduce a contact resistance.

However, a deep cavity recess shaping requires a biased plasma reactive ion etch (RIE) process, which damages the source/drain region (e.g., disruption of silicon (Si) or silicon germanium (SiGe) crystalline lattice by ion bombardment) and inhibits additional growth on the damaged surface to form a contact epitaxial layer. Such damages are exacerbated by an RIE process using large mass/size ions due to near-surface collisions with high momentum transfer. Typically, post process treatments to remove defective layers are performed, but the post treatments can result in contact resistance increase.

Therefore, there is a need for methods that can improve a deep cavity recess shaping in a surface of a source/drain region at a bottom of a contact trench without damaging the surface.

### SUMMARY

Embodiments of the present disclosure provide a method of forming an electrical contact in a semiconductor structure. The method includes performing a cavity shaping process to form a cavity in an exposed surface of an epitaxially grown region within a contact trench in a dielectric layer formed over a semiconductor region, the cavity shaping process including a reactive ion etching (RIE) process using a process gas consisting of an etch gas and a supporting inert gas including species less than 40 atomic mass (amu), and performing a selective epitaxial deposition process to form a contact epitaxial layer on an exposed surface of the cavity.

Embodiments of the present disclosure also provide a method of forming an electrical contact in a semiconductor structure. The method includes performing a first selective epitaxial deposition process to form a source/drain (S/D) region in a contact trench in a dielectric layer formed on a semiconductor region, performing a cavity shaping process to form a cavity in an exposed surface of the S/D region within the contact trench, the cavity shaping process including a reactive ion etching (RIE) process using a process gas consisting of an etch gas and a supporting inert gas including species less than 40 atomic mass (amu), performing a second selective epitaxial deposition process to form a contact epitaxial layer on an exposed surface of the cavity, performing a silicide forming process to form a cavity contact over the contact epitaxial layer within the contact trench, and performing a metal filling process to form a contact plug in the contact trench.

Embodiments of the present disclosure further provide a method of forming an electrical contact in a semiconductor structure. The method includes performing a first selective epitaxial deposition process to form a source/drain (S/D) region in a contact trench in a dielectric layer formed on a semiconductor region, performing a cavity shaping process to form a cavity in an exposed surface of the S/D region within the contact trench, the cavity shaping process including a reactive ion etching (RIE) process using a process gas consisting of an etch gas and a supporting inert gas including species less than 40 atomic mass (amu), performing a second selective epitaxial deposition process to form a contact epitaxial layer on an exposed surface of the cavity, performing a silicide forming process to form a cavity contact over the contact epitaxial layer within the contact trench, performing a blanket deposition process to form a barrier layer on exposed inner surfaces of the contact trench and on the exposed surface of the dielectric layer, and performing a metal filling process to form a contact plug in the contact trench.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic top view of a multi-chamber processing system according to one or more embodiments of the present disclosure.

FIG. 2 depicts a process flow diagram of a method of forming a contact layer in semiconductor structure according to one or more embodiments of the present disclosure.

FIGS. 3A, 3B, 3C, 3D, 3E, and 3F are cross-sectional views of a portion of a semiconductor structure corresponding to various states of the method of FIG. 2.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The embodiments described herein provide methods for forming a cavity in a contact trench of a structure that is used to form a CMOS device, to increase a contact interface area, without damaging surfaces of an underlying source/drain region. The methods include a cavity shaping process using only low mass species in a reactive ion etching (RIE) process, which reduces momentum transfer of the species to a surface of the source/drain region, thus reducing disruption of silicon (Si) or silicon germanium (SiGe) crystalline lattice by ion bombardment.

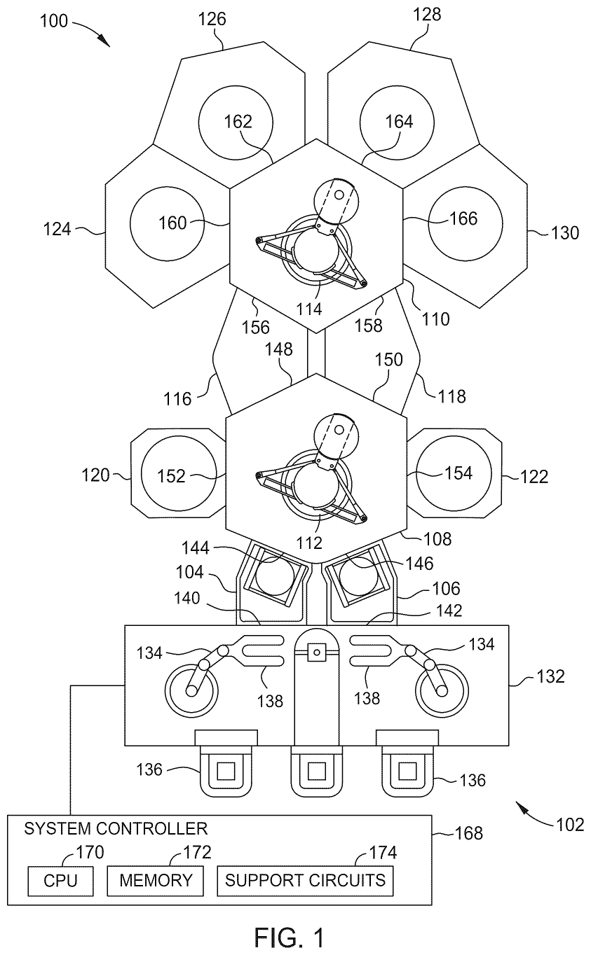

FIG. 1 is a schematic top view of a multi-chamber processing system 100, according to one or more embodiments of the present disclosure. The processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, substrates in the processing system 100 can be processed in and transferred between the various chambers without exposing the substrates to an ambient environment exterior to the processing system 100 (e.g., an atmospheric ambient environment such as may be present in a fab). For example, the substrates can be processed in and transferred between the various chambers maintained at a low pressure (e.g., less than or equal to about 300 Torr) or vacuum environment without breaking the low pressure or vacuum environment among various processes performed on the substrates in the processing system 100. Accordingly, the processing system 100 may provide for an integrated solution for some processing of substrates.

Examples of a processing system that may be suitably modified in accordance with the teachings provided herein include the Endura®, Producer® or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 1, the factory interface 102 includes a docking station 132 and factory interface robots 134 to facilitate transfer of substrates. The docking station 132 is adapted to accept one or more front opening unified pods (FOUPs) 136. In some examples, each factory interface robot 134 generally includes a blade 138 disposed on one end of the respective factory interface robot 134 adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The transfer chamber 108 further has respective ports 148, 150 coupled to the holding chambers 116, 118 and respective ports 152, 154 coupled to processing chambers 120, 122. Similarly, the transfer chamber 110 has respective ports 156, 158 coupled to the holding chambers 116, 118 and respective ports 160, 162, 164, 166 coupled to processing chambers 124, 126, 128, 130. The ports 144, 146, 148, 150, 152, 154, 156, 158, 160, 162, 164, 166 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough. Otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 134 transfers a substrate from a FOUP 136 through a port 140 or 142 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing and the holding chambers 116, 118 through the respective ports 148, 150 for holding to await further transfer. Similarly, the transfer robot 114 is capable of accessing the substrate in the holding chamber 116 or 118 through the port 156 or 158 and is capable of transferring the substrate to and/or between any of the processing chambers 124, 126, 128, 130 through the respective ports 160, 162, 164, 166 for processing and the holding chambers 116, 118 through the respective ports 156, 158 for holding to await further transfer. The transfer and holding of the substrate within and among the various chambers can be in the low pressure or vacuum environment provided by the gas and pressure control system.

The processing chambers 120, 122, 124, 126, 128, 130 can be any appropriate chamber for processing a substrate. In some examples, the processing chamber 120 can be capable of performing an etch process, the processing chamber 122 can be capable of performing a cleaning process, the processing chamber 124 can be capable of performing a selective removal process, and the processing chambers 126, 128, 130 can be capable of performing respective epitaxial growth processes. The processing chamber 120 may be a Selectra™ Etch chamber available from Applied Materials of Santa Clara, Calif. The processing chamber 122 may be a SiCoNi™ Pre-clean chamber available from Applied Materials of Santa Clara, Calif. The processing chamber 126, 128, or 130 may be a Centura™ Epi chamber available from Applied Materials of Santa Clara, Calif.

A system controller 168 is coupled to the processing system 100 for controlling the processing system 100 or components thereof. For example, the system controller 168 may control the operation of the processing system 100 using a direct control of the chambers 104, 106, 108, 110, 116, 118, 120, 122, 124, 126, 128, 130 of the processing system 100 or by controlling controllers associated with the chambers 104, 106, 108, 110, 116, 118, 120, 122, 124, 126, 128, 130. In operation, the system controller 168 enables data collection and feedback from the respective chambers to coordinate performance of the processing system 100.

The system controller 168 generally includes a central processing unit (CPU) 170, memory 172, and support circuits 174. The CPU 170 may be one of any form of a general purpose processor that can be used in an industrial setting. The memory 172, or non-transitory computer-readable medium, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. When the computer instruction code is executed by the CPU 170, the CPU 170 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

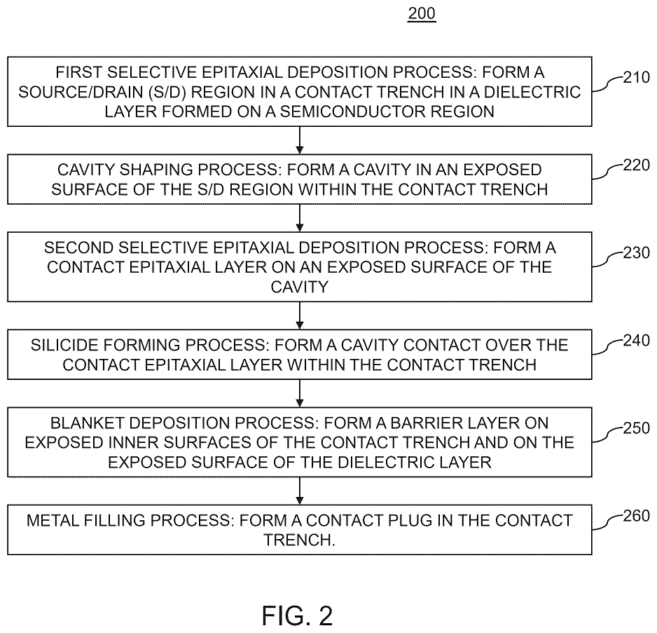

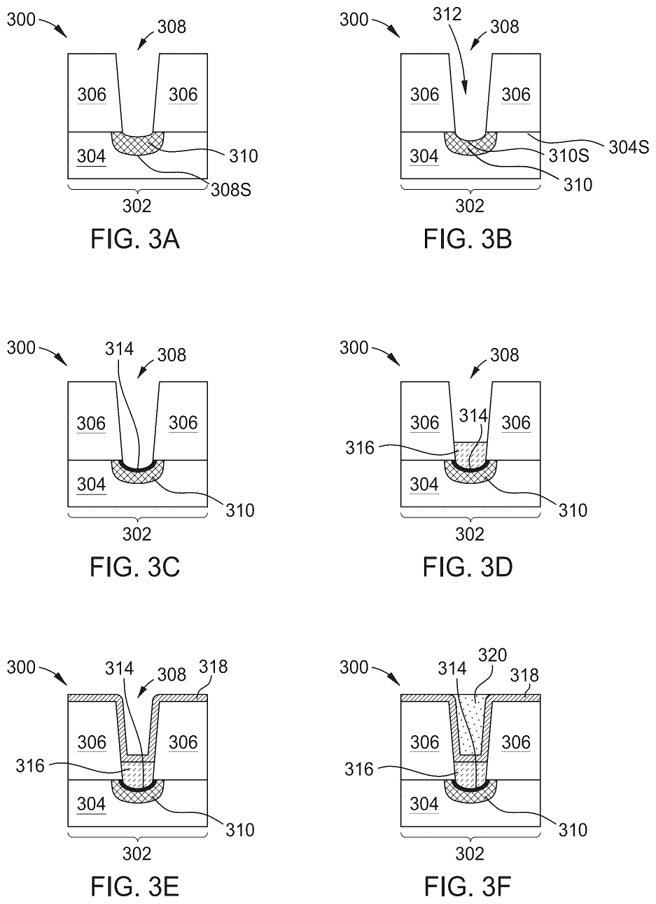

FIG. 2 depicts a process flow diagram of a method 200 of forming a contact layer in a semiconductor structure 300 according to one or more embodiments of the present disclosure. FIGS. 3A, 3B, 3C, 3D, 3E, and 3F are cross-sectional views of a portion of the semiconductor structure 300 corresponding to various states of the method 200. It should be understood that FIGS. 3A, 3B, 3C, 3D, 3E, and 3F illustrate only partial schematic views of the semiconductor structure 300, and the semiconductor structure 300 may contain any number of transistor sections and additional materials having aspects as illustrated in the figures. It should also be noted that although the method illustrated in FIG. 2 is described sequentially, other process sequences that include one or more operations that have been omitted and/or added, and/or has been rearranged in another desirable order, fall within the scope of the embodiments of the disclosure provided herein.

As shown in FIG. 3A, the semiconductor structure 300 may include a portion of a CMOS device 302, which can be an n-type MOS device or a p-type MOS device formed on a substrate that includes a semiconductor region 304.

The term “substrate” as used herein refers to a layer of material that serves as a basis for subsequent processing operations and includes a surface to be cleaned. The substrate may be a silicon based material or any suitable insulating materials or conductive materials as needed. The substrate may include a material such as crystalline silicon (e.g., Si<100> or Si<111>), silicon oxide, strained silicon, silicon germanium, doped or undoped polysilicon, doped or undoped silicon wafers and patterned or non-patterned wafers, silicon on insulator (SOI), carbon doped silicon oxides, silicon nitride, doped silicon, germanium, gallium arsenide, glass, or sapphire.

In some embodiments, the CMOS device 302 is an n-type MOS device of a plurality of n-type transistor devices including a semiconductor region 304 formed of a first material, such as silicon (Si).

In some embodiments, the CMOS device 302 is a p-type MOS device of a plurality of p-type transistor devices including a semiconductor region 304 formed of a second material.

The first and second materials include materials having differing compositions, such that the second material can be selectively etched relative to the first material (i.e., an etch rate of the second material is higher than an etch rate of the first material). The etch selectivity of the second material (i.e., a ratio of the etch rate of the second material to the etch rate of the first material) is between about 10:1 to 500:1. Other example combinations of the first material and the second material include silicon (Si)/silicon germanium (SiGe), germanium (Ge)/silicon germanium (SiGe), or silicon (Si)/germanium tin (GeSn), respectively.

The semiconductor structure 300 further includes a dielectric layer 306 over the semiconductor region 304 having a contact trench 308 in the dielectric layer 306.

The semiconductor region 304 may be formed using any suitable deposition technique, such as epitaxial (Epi) deposition, chemical vapor deposition (CVD), atomic layer deposition (ALD), or physical vapor deposition (PVD).

The dielectric layer 306 may be formed of a dielectric material, such as silicon dioxide (SiO₂) or silicon nitride (Si₃N₄).

The contact trench 308 may be formed by a patterning technique, such as a lithography and an anisotropic remote plasma assisted dry etch process, such as a reactive ion etching (RIE) process, using a plasma formed from a gas including hydrogen (H), argon (Ar), helium (He), or a combination thereof, performed in a processing chamber, such as the processing chamber 122 shown in FIG. 1.

The method 200 begins with block 210, in which a first selective epitaxial deposition process is performed to form a source/drain (S/D) region 310 on a bottom surface 308S of the contact trench 308, as shown in FIG. 3A. The first selective deposition process may be performed in a processing chamber, such as the processing chamber 126, 128, or 130 shown in FIG. 1. The first selective deposition process may be performed without breaking vacuum environment in a multi-chamber processing system, such as the multi-chamber processing system 100 shown in FIG. 1.

The S/D region 310 of the n-type MOS device 302 may be formed of the first material epitaxially grown and doped with n-type dopants such as phosphorus (P), antimony (Sb), with the concentration between about 10²⁰ cm⁻³ and about 5×10²¹ cm⁻³, depending upon the desired conductive characteristic of the n-type MOS device 302. The S/D region 310 of the p-type MOS device 302 may be formed of the second material epitaxially grown and doped with p-type dopants such as boron (B) or gallium (Ga), with the concentration of between about 10²⁰ cm⁻³ and about 5×10²¹ cm⁻³, depending upon the desired conductive characteristic of the p-type MOS device 302.

In block 220, a cavity shaping process is performed to form a cavity 312 in an exposed surface 310S of the S/D region 310 within the contact trench 308, as shown in FIG. 3B. The cavity shaping process may be performed in an etch chamber, such as the processing chamber 120 shown in FIG. 1. The cavity shaping process may be performed without breaking vacuum environment in a multi-chamber processing system, such as the multi-chamber processing system 100 shown in FIG. 1.

The cavity shaping process includes an isotropic etch process. In some embodiments, the cavity shaping process includes an anisotropic etch process and a subsequent isotropic etch process.

The anisotropic etch process includes an anisotropic remote plasma assisted dry etch process, such as a reactive ion etching (RIE) process, in which a process gas including an etch gas and supporting inert gas, such as helium (He), is delivered to the semiconductor structure 300 while the substrate is biased. The plasma effluents directionally bombard the exposed surface 310S of the S/D region 310 within the contact trench 308 and form the cavity 312. The etch gas may include a halogen containing gas, such as chlorine (Cl₂), hydrogen chloride (HCl), chloromethane (methyl chloride, CH₃Cl), or hydrogen fluoride (HF).

In the embodiments described herein, the supporting inert gas includes low mass species less than 40 atomic mass (amu), such as helium (He, 4 amu), hydrogen (H₂, 2 amu), neon (Ne, 20 amu), or nitrogen (N₂, 28 amu), but does not include heavy mass species, such as argon (Ar, 40 amu).

In one example, the inventors have observed an RIE process using chlorine (Cl₂,) and argon (Ar) in the process gas causes damage on an epitaxially grown boron (B)-doped silicon germanium (SiGe) surface, which prevented epitaxial regrowth on the etched surface. In another example, the inventors further observed an RIE process using chlorine (Cl₂) and helium (He) in the process gas did not cause damage on an epitaxially grown silicon germanium (SiGe) surface that prevents epitaxial regrowth on the etched surface. Thus, by adjusting composition of supporting inert gas, for example, helium (He) only, an RIE process can be performed without causing damage on the surface 310S of the S/D region 310 during the cavity shaping process.

The isotropic etch process includes an isotropic plasma etch process, such as a dry chemical etch process, in which a process gas including a halogen containing gas, such as chlorine (Cl₂), and inert gas, such as helium (He) is delivered to the semiconductor structure 300 while the substrate is not biased.

The cavity shaping process may remove a layer of between about 2 nm and about 3 nm from the surface 310S of the S/D region 310, and the resulting cavity 312 may have a width of between about 10 nm and about 30 nm, such as between about 10 nm and about 15 nm, and a depth from an un-etched surface 304S of the semiconductor region 304 of between about 2 nm and about 30 nm, such as between about 5 nm and about 15 nm. The cavity 312 enlarges a contact area between the S/D region 310 to a contact plug to be formed within the contact trench 308, to minimize contact resistivity without increasing a critical dimension (CD) of the contact trench 308, leading to an improved device performance.

The cavity shaping process is also used to refresh (e.g., etching a surface of about a few nanometers that is potentially contaminated with remaining oxygen, nitrogen, or carbon) and prepare pure contamination free exposed surfaces of the cavity 312 on which a contact (e.g., metal silicide) can be formed within the cavity 312 in a subsequent deposition process. The cavity shaping process may also be used to optimize a device stress.

In block 230, a second selective epitaxial deposition process is performed to form a contact epitaxial layer 314 on the surface 310S of the S/D region 310 within the cavity 312, as shown in FIG. 3C. The second selective deposition process may be performed in a processing chamber, such as the processing chamber 126, 128, or 130 shown in FIG. 1. The second selective deposition process may be performed without breaking vacuum environment in a multi-chamber processing system, such as the multi-chamber processing system 100 shown in FIG. 1.

The contact epitaxial layer 314 in the n-type MOS device 302 may be formed of the first material, lightly doped with n-type dopants such as phosphorus (P), antimony (Sb), with the concentration between about 1×10¹⁸ cm⁻³ and about 5×10²¹ cm⁻³, depending upon the desired conductive characteristic of the n-type MOS device 302. The contact epitaxial layer 314 in the p-type MOS device 302 may be formed of the second material, lightly doped with p-type dopants such as boron (B) or gallium (Ga), with the concentration of between about 1×10¹⁸ cm⁻³ and about 5×10²¹ cm⁻³, depending upon the desired conductive characteristic of the p-type MOS device 302.

The contact epitaxial layer 314 is formed as an interface between the S/D region 304 and a metal contact plug to be formed within the contact trench 308, to minimize parasitic resistance.

In block 240, a silicide forming process is performed to form a cavity contact 316 in the cavity 312, as shown in FIG. 3D. The cavity contact 316 interfaces with the S/D region 310 and a contact plug to be formed within the contact trench 308, and provides an electrical connection therebetween. The silicide forming process includes a deposition process, such as chemical vapor deposition (CVD), physical vapor deposition (PVD), or the like performed in a processing chamber, such as the processing chamber 126, 128, or 130 shown in FIG. 1. The cavity contact formation process may be performed without breaking vacuum environment in a multi-chamber processing system, such as the multi-chamber processing system 100 shown in FIG. 1.

In some embodiments, the cavity contact 316 is formed of a first metal material, such as molybdenum (Mo), ruthenium (Ru), or silicide thereof, on the semiconductor region 304 of p-type. In the deposition process, a deposition gas including a metal source, such as a molybdenum (Mo)-containing halide precursor, or a ruthenium (Ru)-containing organometallic that includes ruthenium (Ru), is used. The silicide forming process may be performed at a temperature of between about 240° C. and about 450° C. and at a pressure of between 3 Torr and 300 Torr. During the deposition process, argon (Ar) gas may be supplied at a flow rate of between about 0 sccm and about 1000 sccm, and hydrogen (H₂) gas may be supplied at a flow rate of between about 500 sccm and about 15000 sccm, for example.

In some embodiments, the cavity contact 316 is formed of a second metal material, such as titanium (Ti), cobalt (Co), nickel (Ni), tantalum (Ta), lanthanum (La), yttrium (Y), hafnium (Hf), zirconium (Zr), or silicide thereof, formed on the semiconductor region 304 of n-type. In the deposition process, a deposition gas including a metal source, such as a precursor containing titanium (Ti), tantalum (Ta), cobalt (Co), nickel (Ni), or a combination thereof is used. The deposition process may be performed at a temperature of between about 300° C. and about 800° C. and at a pressure of between 1° Torr and 50° Torr.

A cycle of the silicide forming process may be repeated as needed to obtain a desired thickness of the cavity contact 316, for example, between about 5 times and about 1000 times.

In block 250, a blanket deposition process is performed to form a barrier metal layer 318 on the exposed inner surfaces of the contact trench 308, and the exposed surface of the dielectric layer 306, as shown in FIG. 3E. The barrier metal layer 318 protects the cavity contact 316 and allows nucleation and growth of a contact plug in the contact trench 308. The barrier metal layer 318 may be formed of a barrier metal material that is titanium nitride (TiN), or tantalum nitride (TaN). The blanket deposition process may be performed without breaking vacuum environment in a multi-chamber processing system, such as the multi-chamber processing system 100 shown in FIG. 1.

In block 260, a metal filling process is performed to form a contact plug 320 in the contact trench 308, as shown in FIG. 3F. The contact plug 320 may be formed of contact plug metal material, such as tungsten (W), cobalt (Co), ruthenium (Ru), or molybdenum (Mo). The contact plug 320 may include a metal that has a desirable work function. The metal filling process may include a chemical vapor deposition (CVD) process using a tungsten-containing precursor, such as WF₆, or a cobalt-containing precursor, in a processing chamber, such as the processing chamber 126, 128, or 130 shown in FIG. 1.

After the metal filling process, the semiconductor structure 300 may be planarized, by use of a chemical mechanical planarization (CMP) process.

The embodiments described herein provide methods for forming a cavity in a contact trench of a structure that is used to form a CMOS device, to increase a contact interface area, without damaging surfaces of an underlying source/drain region. The methods include a cavity shaping process using only low mass species in a reactive ion etching (RIE) process, which reduces momentum transfer of the species to a surface of the source/drain region, thus reducing disruption of silicon (Si) or silicon germanium (SiGe) crystalline lattice by ion bombardment.

While the foregoing is directed to embodiments of the present disclosure, other and further embodiments of the disclosure may be devised without departing from the basic scope thereof, and the scope thereof is determined by the claims that follow.

1. A method of forming an electrical contact in a semiconductor structure, comprising:
performing a cavity shaping process to form a cavity in an exposed surface of an epitaxially grown region within a contact trench in a dielectric layer formed over a semiconductor region, the cavity shaping process comprising:
a reactive ion etching (RIE) process using a process gas consisting of an etch gas and a supporting inert gas including species less than 40 atomic mass (amu); and
performing a selective epitaxial deposition process to form a contact epitaxial layer on an exposed surface of the cavity.

2. The method of claim 1, wherein:
the etch gas comprises a halogen containing gas selected from the group consisting of chlorine (Cl₂), hydrogen chloride (HCl), chloromethane (methyl chloride, CH₃Cl), and hydrogen fluoride (HF), and
the supporting inert gas comprises a gas selected from the group consisting of helium (He), hydrogen (H₂), neon (Ne), and nitrogen (N₂).

3. The method of claim 1, wherein:
the semiconductor region comprises silicon, and
the epitaxially grown region comprises silicon doped n-type dopants.

4. The method of claim 1, wherein:
the semiconductor region comprises silicon germanium, and
the epitaxially grown region comprises silicon germanium doped with p-type dopants.

5. The method of claim 1, further comprising:
performing a silicide forming process to form a cavity contact over the contact epitaxial layer within the contact trench; and
performing a metal filling process to form a contact plug in the contact trench.

6. The method of claim 5, wherein:
the cavity contact comprises a material selected from the group consisting of molybdenum (Mo) silicide, ruthenium (Ru) silicide, and titanium (Ti) silicide, and
the contact plug comprises tungsten (W).

7. The method of claim 5, further comprising:
subsequent to the silicide forming process and prior to the metal filling process, performing a blanket deposition process to form a barrier layer on exposed inner surfaces of the contact trench and on the exposed surface of the dielectric layer.

8. The method of claim 7, wherein the barrier layer comprises titanium nitride (TiN) or tantalum nitride (TaN).

9. A method of forming an electrical contact in a semiconductor structure, comprising:
performing a first selective epitaxial deposition process to form a source/drain (S/D) region in a contact trench in a dielectric layer formed on a semiconductor region;
performing a cavity shaping process to form a cavity in an exposed surface of the S/D region within the contact trench, the cavity shaping process comprising:
a reactive ion etching (RIE) process using a process gas consisting of an etch gas and a supporting inert gas including species less than 40 atomic mass (amu);
performing a second selective epitaxial deposition process to form a contact epitaxial layer on an exposed surface of the cavity;
performing a silicide forming process to form a cavity contact over the contact epitaxial layer within the contact trench; and
performing a metal filling process to form a contact plug in the contact trench.

10. The method of claim 9, wherein:
the etch gas comprises a halogen containing gas selected from the group consisting of chlorine (Cl₂), hydrogen chloride (HCl), chloromethane (methyl chloride, CH₃Cl), and hydrogen fluoride (HF), and
the supporting inert gas comprises a gas selected from the group consisting of helium (He), hydrogen (H₂), neon (Ne), and nitrogen (N₂).

11. The method of claim 9, wherein:
the semiconductor region comprises silicon, and
the S/D region comprises silicon doped n-type dopants.

12. The method of claim 9, wherein:
the semiconductor region comprises silicon germanium, and
the S/D region comprises silicon germanium doped with p-type dopants.

13. The method of claim 9, wherein:
the cavity contact comprises a material selected from the group consisting of molybdenum (Mo) silicide, ruthenium (Ru) silicide, and titanium (Ti) silicide, and
the contact plug comprises tungsten (W).

14. The method of claim 9, further comprising:
subsequent to the silicide forming process and prior to the metal filling process, performing a blanket deposition process to form a barrier layer on exposed inner surfaces of the contact trench and on the exposed surface of the dielectric layer.

15. The method of claim 14, wherein the barrier layer comprises titanium nitride (TiN) or tantalum nitride (TaN).

16. A method of forming an electrical contact in a semiconductor structure, comprising:
performing a first selective epitaxial deposition process to form a source/drain (S/D) region in a contact trench in a dielectric layer formed on a semiconductor region;
performing a cavity shaping process to form a cavity in an exposed surface of the S/D region within the contact trench, the cavity shaping process comprising:
a reactive ion etching (RIE) process using a process gas consisting of an etch gas and a supporting inert gas including species less than 40 atomic mass (amu);
performing a second selective epitaxial deposition process to form a contact epitaxial layer on an exposed surface of the cavity;
performing a silicide forming process to form a cavity contact over the contact epitaxial layer within the contact trench;
performing a blanket deposition process to form a barrier layer on exposed inner surfaces of the contact trench and on the exposed surface of the dielectric layer; and
performing a metal filling process to form a contact plug in the contact trench.

17. The method of claim 16, wherein:
the etch gas comprises a halogen containing gas selected from the group consisting of chlorine (Cl₂), hydrogen chloride (HCl), chloromethane (methyl chloride, CH₃Cl), and hydrogen fluoride (HF), and
the supporting inert gas comprises a gas selected from the group consisting of helium (He), hydrogen (H₂), neon (Ne), and nitrogen (N₂).

18. The method of claim 16, wherein:
the semiconductor region comprises silicon, and
the S/D region comprises silicon doped n-type dopants.

19. The method of claim 16, wherein:
the semiconductor region comprises silicon germanium, and
the S/D region comprises silicon germanium doped with p-type dopants.

20. The method of claim 16, further comprising:
performing a silicide forming process to form a cavity contact over the contact epitaxial layer within the contact trench; and
performing a metal filling process to form a contact plug in the contact trench, wherein:
the cavity contact comprises a material selected from the group consisting of molybdenum (Mo) silicide, ruthenium (Ru) silicide, and titanium (Ti) silicide,
the contact plug comprises tungsten (W), and
the barrier layer comprises titanium nitride (TiN) or tantalum nitride (TaN).
